(19) United States
(12) Patent Application Publication
(10) Pub. No.: US 2025/0189883 A1
(43) Pub. Date: Jun. 12, 2025

(54) MASK ASSEMBLY

(71) Applicant: Samsung Display Co., Ltd., Yongin-si (KR)

(72) Inventors: WONYOUNG JANG, Yongin-si (KR); JONGDAE LEE, Yongin-si (KR); SEUNGJU HONG, Yongin-si (KR); JONGSUNG PARK, Yongin-si (KR)

(73) Assignee: Samsung Display Co., Ltd., Yongin-si (KR)

(21) Appl. No.: 18/924,550

(22) Filed: Oct. 23, 2024

(30) Foreign Application Priority Data
Dec. 12, 2023 (KR) 10-2023-0179196

(51) Int. Cl. G03F 1/64; C23C 14/04; H10K 71/16

(52) U.S. Cl. CPC G03F 1/64; C23C 14/042; H10K 71/166

(57) ABSTRACT

A mask assembly includes a stage, a mask frame disposed on an upper surface of the stage, and a mask disposed on an upper surface of the mask frame. The mask frame includes a frame opening bounded on first sides extending in a first direction and second sides extending in a second direction transverse to the first direction. A lower surface of the mask frame includes a first surface surrounding the frame opening in a plan view, and a second surface adjacent to at least one corner among corners of the mask frame in the plan view. The first surface is disposed on the upper surface of the stage. The second surface is spaced apart from the upper surface of the stage in a third direction transverse to both the first direction and the second direction.

### CROSS-REFERENCE TO RELATED APPLICATION(S)

This U.S. non-provisional patent application claims priority to and the benefits of Korean Patent Application No. 10-2023-0179196 under 35 U.S.C. § 119, filed in the Korean Intellectual Property Office on Dec. 12, 2023, the entire contents of which are hereby incorporated by reference.

### BACKGROUND

### 1. Technical Field

The disclosure generally relates to a mask assembly.

### 2. Description of the Related Art

Display devices typically output a video or an image through a display region to provide various visual information to a user. Among the display devices, an organic light-emitting display device has a relatively wide viewing angle, relatively excellent contrast ratio, and relatively high (or fast) response speed. A display region of such an organic light-emitting display device may include pixels. The pixels may form the display region through a deposition process of a deposition material.

A deposition apparatus may include (or utilize) a mask, a mask frame, and a stage as part of one or more stages of deposition. The mask may be stretched and fixed to the mask frame. The mask frame may be deformed due to the stretching of the mask.

The background provided herein is for the purposes of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects provide a mask assembly capable of reducing frictional force generated between a mask frame and a stage disposed on a lower surface of the mask frame.

Additional aspects will be set forth in the detailed description, which follows, and in part, will be apparent from the disclosure, or may be learned by practice of the disclosed embodiments and/or the claimed subject matter.

According to some embodiments, a mask assembly includes a stage, a mask frame, and a mask. The mask frame is disposed on an upper surface of the stage. The mask frame includes a frame opening bounded on first sides extending in a first direction and second sides extending in a second direction transverse to the first direction. The mask is disposed on an upper surface of the mask frame. A lower surface of the mask frame includes a first surface surrounding the frame opening in a plan view, and a second surface adjacent to at least one corner among corners of the mask frame in the plan view. The first surface is disposed on the upper surface of the stage. The second surface is spaced apart from the upper surface of the stage in a third direction transverse to both the first direction and the second direction.

In some embodiments, a first distance between the second surface and the upper surface of the stage in the third direction may be greater than a second distance between the first surface and the upper surface of the stage in the third direction.

In some embodiments, a difference between the first and second distances may be in a range of about 0.05 mm to about 0.15 mm.

In some embodiments, the lower surface of the mask frame may further include a third surface. The third surface may include a (3-1)-th surface extending in the second direction and a (3-2)-th surface extending in the first direction. A fourth distance between the third surface and the upper surface of the stage in the third direction may be greater than the first distance.

In some embodiments, the second surface may include a (2-1)-th surface extending in the second direction along a second side among the second sides of the mask frame, a (2-2)-th surface adjacent to a corner among the corners of the mask frame, and a (2-3)-th surface extending in the first direction along a first side among the first sides of the mask frame.

In some embodiments, in the plan view, the (3-1)-th surface may be disposed between the first surface and the (2-1)-th surface, and in the plan view, the (3-2)-th surface may be disposed between the first surface and the (2-3)-th surface.

In some embodiments, the first surface may include a (1-1)-th surface adjacent to the frame opening, a (1-2)-th surface extending in the second direction along a second side among the second sides of the mask frame, and a (1-3)-th surface extending in the first direction along a first side among the first sides of the mask frame. In the plan view, the (3-1)-th surface may be disposed between the (1-1)-th surface and the (1-2)-th surface. In the plan view, the (3-2)-th surface may be disposed between the (1-1)-th surface and the (1-3)-th surface.

In some embodiments, the (3-1)-th surface may extend in the second direction from one first side of the mask frame to another first side of the mask frame. The one first side of the mask frame and the another first side of the mask frame may oppose each other in the second direction. The (3-2)-th surface may extend in the first direction from one second side of the mask frame to another second side of the mask frame. The one second side of the mask frame and the another second side of the mask frame may oppose each other in the first direction.

In some embodiments, the second surface may be one of a plurality of second surfaces. Each of the plurality of second surfaces may be disposed adjacent to a respective corner among the corners of the mask frame. The (3-1)-th surface may be disposed between second surfaces among the plurality of second surfaces adjacent to each other in the second direction. The (3-2)-th surface may be disposed between second surfaces among the plurality of second surfaces adjacent to each other in the first direction.

In some embodiments, the mask frame may include a first portion including the first surface and the second surface, and a second portion extending from an upper surface of the first portion. The second portion may protrude toward the frame opening further than the first portion. Inner surfaces of the first portion and the second portion bounding respective portions of the frame opening may be inclined from at least one of the first direction and the second direction.

In some embodiments, the frame opening may include a first opening bounded by the inner surfaces of the first portion, and a second opening bounded by the inner surfaces of the second portion. The first opening may be fluidically connected with the second opening within the mask frame.

In some embodiments, the mask assembly may further include a first stick disposed between the mask frame and the mask in the third direction and a second stick disposed between the first stick and the mask in the third direction. The first stick may extend in the first direction. The second stick may extend in the second direction. Each of the first stick and the second stick may be disposed in a corresponding groove in an upper surface of the second portion.

According to some embodiments, a mask assembly may include a stage, a mask frame, and a mask. The mask frame is disposed on an upper surface of the stage. The mask frame includes a frame opening. The mask is disposed on an upper surface of the mask frame such that the upper surface of the mask frame faces the mask in a first direction and a lower surface of the mask frame faces the upper surface of the stage in a second direction opposite the first direction. The lower surface of the mask frame includes a first surface surrounding the frame opening in a plan view, and a second surface adjacent to an edge of the mask frame in the plan view. A step connects the first surface with the second surface.

In some embodiments, a first distance between the second surface and the upper surface of the stage in the first direction may be greater than a second distance between the first surface and the upper surface of the stage in the first direction.

In some embodiments, the lower surface of the mask frame may further include a third surface surrounding the first surface in the plan view. A third distance between the third surface and the upper surface of the stage in the first direction may be greater than the first distance.

In some embodiments, the second surface may extend along at least one first side among first sides of the mask frame that extend in a third direction transverse to the first direction or at least one second side among second sides of the mask frame that extend in a fourth direction transverse to both the first direction and the third direction.

In some embodiments, the second surface may be disposed further from the frame opening than the third surface.

In some embodiments, the second surface may be one of a plurality of second surfaces. Each of the plurality of second surfaces may be disposed adjacent to a respective corner among corners of the mask frame.

In some embodiments, the lower surface of the mask frame may further include a third surface extending in a third direction and a fourth direction in the plan view. Both the third direction and the fourth direction may be transverse to the first direction. The third surface may be disposed between second surfaces among the plurality of second surfaces that are adjacent to each other in the third direction and between second surfaces among the plurality of second surfaces that are adjacent to each other in the fourth direction. The third surface may be disposed further from the frame opening than the first surface.

In some embodiments, the first surface may directly contact the upper surface of the stage.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 schematically illustrates a cross-sectional view of a deposition apparatus according to some embodiments.

FIG. 2A schematically illustrates a perspective view of a mask assembly in FIG. 1 according to some embodiments.

FIG. 2B schematically illustrates an exploded perspective view of the mask assembly in FIG. 2A according to some embodiments.

FIG. 3 schematically illustrates an orthographic view of a stage and a mask frame of the mask assembly in FIG. 2A according to some embodiments.

FIG. 4A schematically illustrates a perspective view of the mask frame in FIG. 3 according to some embodiments.

FIG. 4B schematically illustrates an orthographic view of a lower surface of the mask frame in FIG. 4A according to some embodiments.

FIG. 4C schematically illustrates a perspective detail view of a first region AA1 in FIG. 4A according to some embodiments.

FIG. 5A schematically illustrates a cross-sectional view of the mask assembly in FIG. 4C taken along sectional line II-II′ according to some embodiments.

FIG. 5B schematically illustrates a cross-sectional view of the stage and the mask frame in FIG. 3 taken along sectional line I-I′ according to some embodiments.

FIGS. 6A and 6B schematically illustrate a perspective view and a partial perspective detail view of a lower surface of a mask frame according to some embodiments.

FIGS. 7A, 7B, and 7C schematically illustrate a perspective view, a partial perspective detail view, and a cross-sectional view of a mask frame according to some embodiments.

FIG. 8 schematically illustrates an orthographic view of a display panel manufactured using the mask assembly described in association with FIG. 2A according to some embodiments.

FIG. 9 schematically illustrates a cross-sectional view of a representative pixel in FIG. 8 according to some embodiments.

FIG. 10 schematically illustrates a cross-sectional view of the display panel in FIG. 8 during a stage of the deposition process in FIG. 1 according to some embodiments.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, well-known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite the described order. Also, like reference numerals and/or reference characters denote like elements.

When an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. When, however, an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, opening, etc., that is fluidically connected with at least two other components, volumes, plenums, holes, openings, etc., such that fluid flowing from one of those other components, volumes, plenums, holes openings, etc., to the other or another of those components, volumes, plenums, holes, openings, etc., would first flow through the “fluidically interposed” component before reaching that other or another of those components, volumes, plenums, holes, openings, etc. For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures are fluidically interposed between the two elements that might potentially interrupt fluid flow between the two fluidic elements. For example, in a flow path having a first valve, a second valve, and a third valve sequentially arranged, the first valve would be fluidically adjacent to the second valve, the second valve would be fluidically adjacent to both the first and third valves, and the third valve would be fluidically adjacent to the second valve.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . , or (1), (2), (3), . . . , or the like, in this disclosure and accompanying claims, is to be understood as not conveying any particular order or sequence, except to the extent that such an order or sequence is explicitly indicated. For example, if there are three steps labeled (i), (ii), and (iii), these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within +5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described in detail with reference to the accompanying drawings.

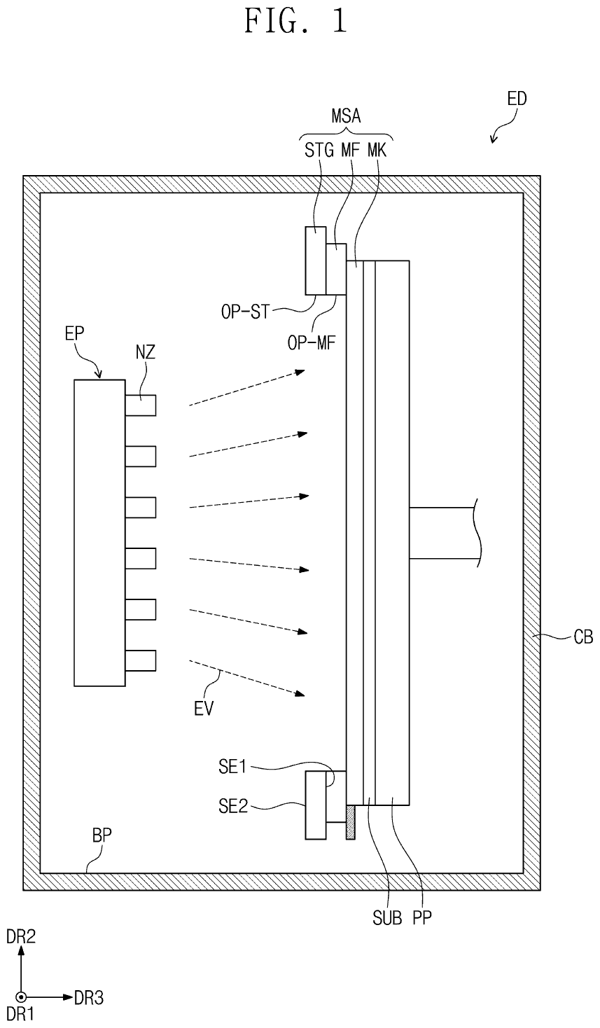

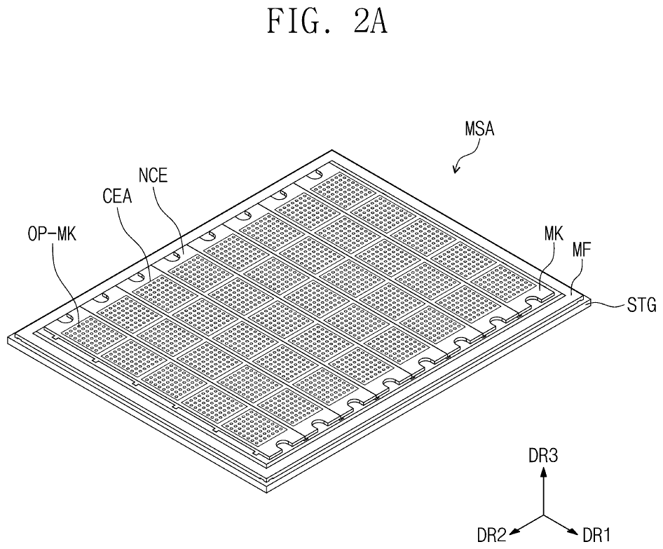

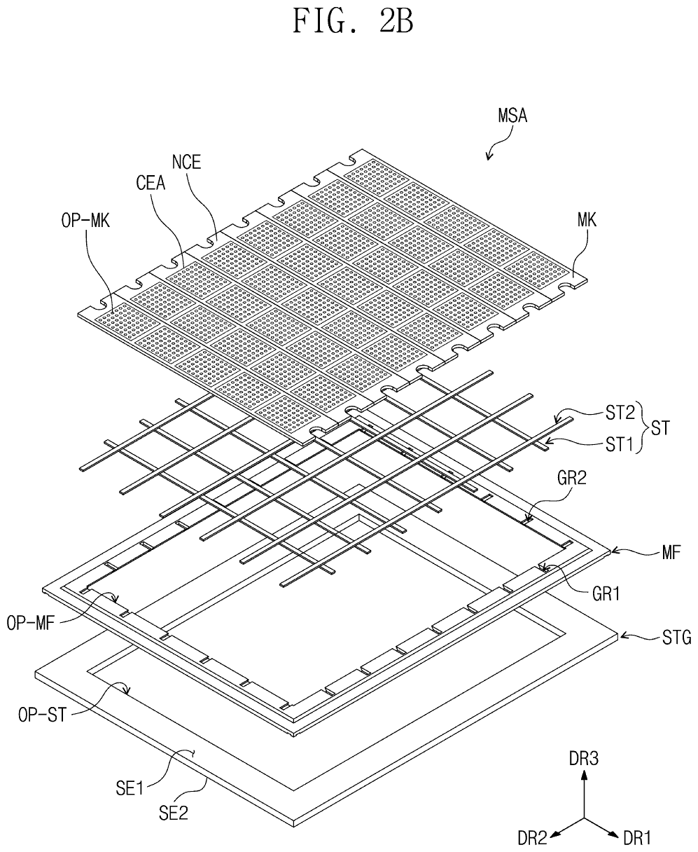

FIG. 1 schematically illustrates a cross-sectional view of a deposition apparatus according to some embodiments. FIG. 2A schematically illustrates a perspective view of a mask assembly in FIG. 1 according to some embodiments. FIG. 2B schematically illustrates an exploded perspective view of the mask assembly in FIG. 2A according to some embodiments.

Referring to FIG. 1, a deposition apparatus ED according to an embodiment may include a chamber CB, a mask assembly MSA, a deposition source EP, and a fixing member PP. The mask assembly MSA may include a stage STG, a mask frame MF, and a mask MK.

The chamber CB may provide an internal space, and the deposition source EP and the mask assembly MSA may be at least partially disposed in the internal space of the chamber CB, but embodiments are not limited thereto. In some cases, the chamber CB may form a closed space, and depositing (or environmental) conditions in the chamber CB may be set to vacuum or a relatively low pressure, such as a pressure below atmospheric pressure. The chamber CB may include at least one gate (or transport port) and may be opened and closed by (or through) the gate. The mask assembly MSA and a substrate SUB may be put into and taken out from the chamber CB through the gate provided in the chamber CB.

The chamber CB may include a bottom surface BP, a ceiling surface, and side walls. The bottom surface BP of the chamber CB may be parallel to a plane defined by a first direction DR1 and a third direction DR3. A direction normal to the bottom surface BP of the chamber CB may be parallel to a second direction DR2.

The fixing member PP may be at least partially disposed inside the chamber CB, and the fixing member PP and the deposition source EP may face each other in the third direction DR3. The substrate SUB may closely adhere to the mask MK through the fixing member PP, but embodiments are not limited thereto. For example, the mask MK may be spaced apart from the substrate SUB, which may be supported in the chamber CB by the fixing member PP. In some embodiments, the fixing member PP may include magnetic bodies that cause, at least in part, the substrate SUB to closely adhere to the mask MK, or vice versa. For example, the magnetic bodies may generate a magnetic and/or electrostatic force that attracts the mask MK toward the fixing member PP with the substrate SUB disposed between the mask MK and the fixing member PP. In this manner, the mask MK and the substate SUB may be closely adhered (e.g., chucked) to the fixing member PP. However, embodiments are not limited thereto, and the fixing member PP may include a robot arm, a jig for holding the mask MK, etc.

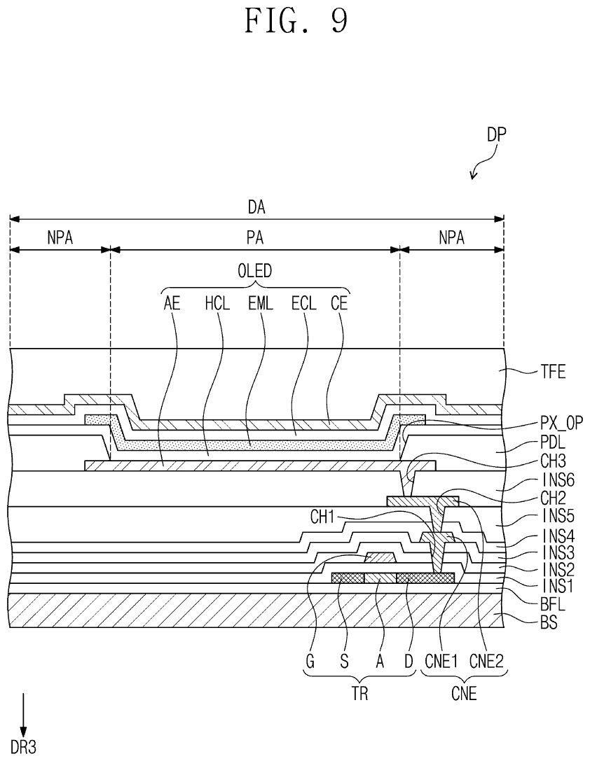

The substrate SUB may be disposed between the mask MK and the fixing member PP. The substrate SUB may be an object to be processed, such as a wafer, etc., and to this end, a deposition material may be deposited on the substrate SUB. In some cases, the substrate SUB may include a supporting substrate and a synthetic resin material may be disposed on the supporting substrate. The deposition material may include an organic light-emitting material for forming a display panel DP (see, e.g., FIG. 9). A deposition material EV, which may be sublimed or vaporized, may be sprayed toward (or distributed adjacent to) the substrate SUB through a nozzle NZ. The deposition material EV may pass through one or more mask openings OP-MK (see also FIG. 2B) of (or in) the mask MK and may be deposited on the substrate SUB. Coupling grooves may be defined in corners of the stage STG to fix the stage STG to a coupling member, which is described in more detail later. The stage STG may be fixed to the coupling member through the coupling grooves by any suitable fastener, e.g., fastening bolts, screws, magnets, rivets, anchors, pins, clips, straps, snaps, rods, etc.

The stage STG may include a mounting surface SE1 and a rear surface SE2 opposing the mounting surface SE1. The mounting surface SE1 and the rear surface SE2 of the stage STG may each be (or form) a plane parallel to the first direction DR1 and the second direction DR2, which is transverse to the first direction DR1.

Hereinafter, a direction substantially perpendicularly transverse to a plane defined by the first direction DR1 and the second direction DR2 is defined as the third direction DR3. In addition, as used herein, the phrase “in a plan view” may be defined as a state of viewing an object in the third direction DR3, or a state of viewing an object in a direction perpendicular to, for instance, an upper surface of the object. In some cases, the direction perpendicular to the upper surface of the object may correspond with the third direction DR3.

Referring to FIGS. 1, 2A, and 2B, in the chamber CB, the stage STG may be disposed between the deposition source EP and the fixing member PP. In the chamber CB, the stage STG may be disposed in a moving path of the deposition material EV supplied from the deposition source EP toward the substrate SUB. In this manner, a position and/or an orientation of the fixing member PP may be controlled before, during, and/or after one or more deposition processes.

The mounting surface SE1 and the rear surface SE2 of the stage STG may be provided (or arranged) substantially perpendicular to the bottom surface BP of the chamber CB, but embodiments are not limited thereto. Accordingly, a deposition process may be performed while a rear surface of each of the mask MK and the mask frame MF disposed on the mounting surface SE1 of the stage STG is substantially perpendicular to the bottom surface BP of the chamber CB. Thus, the mask MK having a relatively large area may be prevented (or at least mitigated) from sagging due to gravity in a vertical deposition process. This, in turn, may not only improve reliability of the deposition process, but also increase throughput and productivity with more consistent and repeatable results.

However, embodiments are not limited thereto. According to some implementations, the mounting surface SE1 and the rear surface SE2 of the stage STG may be provided substantially parallel to the bottom surface BP of the chamber CB, and the rear surface of each of the mask frame MF and the mask MK may be provided substantially parallel to the bottom surface BP of the chamber CB. It is contemplated, however, that the mounting surface SE1 and the rear surface SE2 of the stage STG including the substrate SUB and the mask assembly MSA disposed thereon may, in some deposition scenarios, be angled with respect to the bottom surface BP of the chamber CB.

The stage STG may, in a view perpendicular to the rear surface SE2, have a quadrangular frame shape having at least one short side extending in a first direction DR1 and at least one long side extending in a second direction DR2, but embodiments are not limited thereto. For instance, the stage STG may have any suitable shape, such as a circular, triangular, pentagonal, hexagonal, etc. In some cases, the stage STG may exhibit a freeform shape. A stage opening OP-ST may be defined in the stage STG having, for instance, a quadrangular frame shape. The stage opening OP-ST may have a quadrangular shape in a view perpendicular to rear surface SE2, but embodiments are not limited thereto. For example, the stage opening OP-ST may have any suitable shape, which may be similar to or different from the shape of the stage STG. For convenience, the shape of the stage STG and the stage opening OP-ST will, hereinafter, be assumed to be quadrangular.

Hereinafter, the mounting surface SE1 of the stage STG will be referred to as an upper surface SE1 of the stage STG, and the rear surface SE2 of the stage STG will be referred to as a lower surface SE2 of the stage STG.

The mask frame MF may be disposed on the upper surface SE1 of the stage STG. A lower surface of the mask frame MF may be disposed on the upper surface SE1 of the stage STG. The stage STG may support the mask frame MF.

By way of example, an edge of the mask frame MF may be disposed further inwards than an edge of the stage STG. In a plan view, an area of the mask frame MF may be smaller than an area of the stage STG.

The mask frame MF may have a quadrangular frame shape having at least one short side extending in the first direction DR1 and at least one long side extending in the second direction DR2 in a view perpendicular to an upper surface of the mask frame MF. It is contemplated, however, that the mask frame MF may have any other suitable shape, which may be similar to or different from the shape of the stage STG. A frame opening OP-MF may be defined in the mask frame MF having a quadrangular frame shape. The frame opening OP-MF may have a quadrangular shape in a view perpendicular to the upper surface of mask frame MF, but any other shape may be utilized. The frame opening OP-MF may overlap the stage opening OP-ST. In some cases, a central axis of the frame opening OP-MF extending in, for instance, the third direction DR3 may be axially aligned with a central axis of the stage opening OP-ST. Further, the frame opening OP-MF and the stage opening OP-ST may be continuously defined in the third direction DR3.

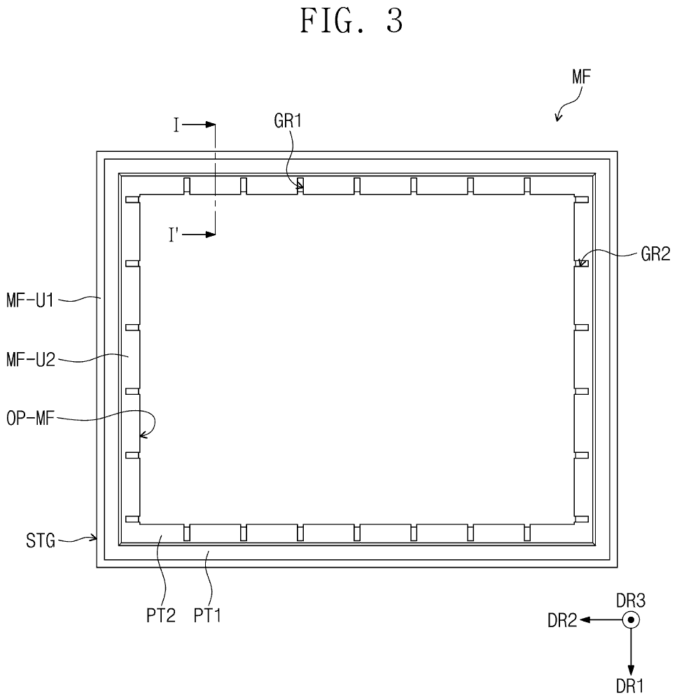

First grooves GR1 arranged (e.g., spaced apart from one another) in the second direction DR2 and second grooves GR2 arranged in the first direction DR1 may be defined (or formed) in an upper surface of the mask frame MF. In a plan view, the first grooves GR1 may be arranged along long sides of the mask frame MF defining the frame opening OP-MF. In a plan view, the second grooves GR2 may be arranged along short sides of the mask frame MF defining the frame opening OP-MF. In some cases, first ends of the first grooves GR1 and first ends of the second grooves GR2 may extend to, and thereby, may be fluidically connected with the frame opening OP-MF (see also FIGS. 3, 4A, 4B, 6A, 7A, and 7B). Second ends of the first grooves GR1 and second ends of the second grooves GR2 may be spaced apart from corresponding outer boundaries of the mask frame MF, but embodiments are not limited thereto. Distances between the first grooves GR1 adjacent to each other in the second direction DR2 may be the same as each other. Distances between the second grooves GR2 adjacent to each other in the first direction DR1 may be the same as each other. In some cases, however, at least one of the distances between adjacent first grooves GR1 and/or at least one of the distances between adjacent second grooves GR2 may be different.

The mask frame MF may have determined or selected rigidity. For example, the mask frame MF may include a metal material, such as stainless steel (SUS), invar (FeNi36), nickel (Ni), cobalt (Co), etc., or any suitable combination thereof. In some cases, the mask frame MF may further include a protective coating, which may prevent or at least reduce the likelihood of arcing, residue build up, corrosion, etching, abrasion, flaking, etc. It is also contemplated that the coating may increase the lifecycle of the mask frame MF by increasing, for instance, the ability to clean and reuse the mask frame MF. In some implementations, the coating may be formed on the mask frame MF as part of being initially exposed to one or more process gases, such as at least one of nitrogen, oxygen, argon, hydrogen, etc.

The mask assembly MSA may further include sticks ST. The sticks ST may include first sticks ST1 and second sticks ST2. The first sticks ST1 may be disposed on the upper surface of the mask frame MF. The first sticks ST1 may be arranged in the second direction DR2 and extend in the first direction DR1. The first sticks ST1 may cross the frame opening OP-MF. A central portion of the first sticks ST1 may overlap the frame opening OP-MF. Two sides of each of the first sticks ST1 opposed to each other in the first direction DR1 may be at least partially disposed in the first grooves GR1.

The second sticks ST2 may be disposed on the first sticks ST1. The second sticks ST2 may cross the first sticks ST1. By way of example, the second sticks ST2 may be disposed on (e.g., directly on) the first sticks ST1. However, embodiments are not limited thereto, and the first sticks ST1 may be disposed on the second sticks ST2. It is also contemplated that the second sticks ST2 may be spaced apart from the first second sticks ST1 in the third direction DR3.

The second sticks ST2 may be arranged in the first direction DR1 and extend in the second direction DR2. By way of example, a length of each of the second sticks ST2 in the second direction DR2 may be greater than a length of each of the first sticks ST1 in the first direction DR1. The second sticks ST2 may cross the frame opening OP-MF. A central portion of the second sticks ST2 may overlap the frame opening OP-MF. Two sides of each of the second sticks ST2 opposed to each other in the second direction DR2 may be at least partially disposed in the second grooves GR2.

The first sticks ST1 and the second sticks ST2 may include a non-magnetic material. For example, the first sticks ST1 and the second sticks ST2 may include aluminum. However, this is merely an example, and a material of the first sticks ST1 and the second sticks ST2 is not limited thereto. Similar to the mask frame MF, the first sticks ST1 and the second sticks ST2 may include a protective coating formed thereon.

Masks MK may be disposed on the upper surface of the mask frame MF. The masks MK may extend in the first direction DR1 and may be arranged in the second direction DR2. The masks MK may each have, in a plan view, a rectangular shape having long sides extending in the first direction DR1 and short sides extending in the second direction DR2. It is contemplated, however, that any other suitable shape may be utilized for the masks MK.

Opposing sides of each of the masks MK may be connected to (and/or supported by) the mask frame MF. The masks MK may be stretched to cover the frame opening OP-MF. By way of example, the masks MK may be stretched in the first direction DR1 due to force acting in the first direction DR1 and a direction opposed to the first direction DR1. The stretched masks MK may be connected to the mask frame MF through, for instance, laser welding, however, any other suitable technique may be utilized, such as electron beam welding, pulse arc welding, ultrasonic welding, spot welding, stir friction welding, etc.

The masks MK may be disposed on the first sticks ST1 and the second sticks ST2. The first sticks ST1 and the second sticks ST2 may prevent (or at least reduce the likelihood of) the masks MK from being separated from the mask frame MF. For instance, the first sticks ST1 and the second sticks ST2 may serve as a support for the masks MK.

The masks MK may include metal. For example, the masks MK may be defined as a fine metal mask. Similar to the mask frame MF, the masks MK may include a protective coating.

Cell regions CEA and peripheral regions NCE may be defined on (or in) upper surfaces of the masks MK. By way of example, the cell regions CEA may have a rectangular shape having a long side in the first direction DR1 and a short side in the second direction DR2. However, a shape of the cell regions CEA is not limited thereto. The peripheral regions NCE may be a portion of the masks MK other than the cell regions CEA. The peripheral regions NCE may surround the cell regions CEA in a plan view.

The cell regions CEA may be arranged in the first direction DR1. By way of example, five cell regions CEA are arranged in the first direction DR1 on the upper surface of each of the masks MK, but the number of the cell regions CEA is not limited thereto. For instance, one or more of the masks MK may include less than five cell regions CEA or may include six or more cell regions CEA.

The cell regions CEA may overlap the frame opening OP-MF in an assembled state of the mask assembly MSA. The cell regions CEA may not overlap the mask frame MF. The first sticks ST1 and the second sticks ST2 may not overlap the cell regions CEA. The first sticks ST1 and the second sticks ST2 may overlap the peripheral regions NCE.

Mask openings OP-MK may be defined in the cell regions CEA. The mask openings OP-MK may be arranged in the first direction DR1 and the second direction DR2. For instance, the mask openings OP-MK may be arranged in a matrix formation, however, any other suitable arrangement may be utilized. In a plan view, the mask openings OP-MK may overlap the frame opening OP-MF in an assembled state of the mask assembly MSA. The stage opening OP-ST, the frame opening OP-MF, and the mask openings OP-MK may be continuously defined in the third direction DR3 in an assembled state of the mask assembly MSA. Accordingly, as illustrated in FIG. 1, the deposition material EV may pass through the stage opening OP-ST, the frame opening OP-MF, and the mask openings OP-MK and may be deposited on the substrate SUB, such as deposited on the substrate SUB according to a pattern of the mask openings OP-MK.

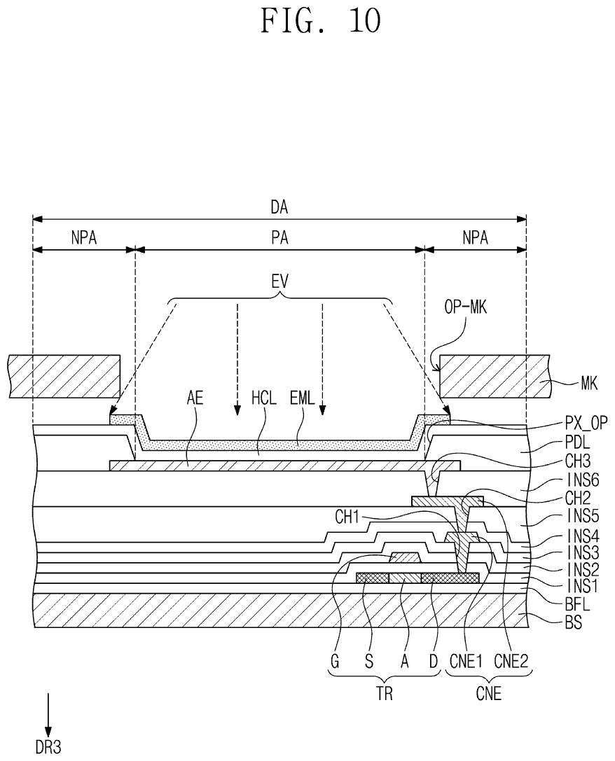

Referring to FIG. 1, the deposition source EP may be disposed inside the chamber CB and may face the fixing member PP in the third direction DR3. The deposition source EP may include a storage in which the deposition material EV is accommodated and at least one nozzle NZ. In some cases, the deposition material EV may be stored remotely and supplied to the deposition source EP via one or more conduits fluidically connected with the deposition source EP. The deposition material EV may include at least one of a metal, an organic material, and an inorganic material. The deposition material EV may be flowed into a plenum volume defined by the chamber CB in a sublimed or vaporized stated. In some cases, the deposition source EP may be configured to sublimate or vaporize the deposition material EV and/or the deposition material may be flowed to the deposition source EP in a sublimed or vaporized state. In some cases, the sublimed or vaporized deposition material EV may be entrained in one or more gases, such as one or more process gases, dilution gases, carrier gases, etc. According to some implementations, the deposition material EV may include an organic light-emitting material for forming a light-emitting layer EML (see, e.g., FIG. 10). As such, sublimed or vaporized deposition material EV may be sprayed toward (or flowed in a direction of) the substrate SUB through nozzles NZ. In some cases, a flow of the deposition material EV may be additionally or alternatively controlled via one or more exhaust ports of the chamber CB. Whatever the case, the deposition material EV may pass through the mask openings OP-MK in the masks MK and may be deposited on the substrate SUB in a pattern corresponding to a pattern of the mask openings OP-MK.

The deposition apparatus ED may further include an additional mechanical device, besides the configuration above, to implement an inline system. The deposition apparatus ED according to some embodiments may further include a coupling member. The coupling member may be fixed to one or more sidewalls of the chamber CB, and the stage STG may be connected to (and/or supported by) the coupling member and stably fixed inside the chamber CB. Thus, even if the stage STG is perpendicularly disposed, a deposition process may be stably performed.

The deposition apparatus ED according to some embodiments may further include an alignment device. The alignment device may adjust positions of the stage STG and the mask frame MF relative to each other and/or relative to, for instance, the bottom surface BP of the chamber CB. Accordingly, a defect may be prevented (or mitigated) from occurring in a case that a flow of the deposition material EV passes through the stage opening OP-ST of the stage STG and the frame opening OP-MF of the mask frame MF and is deposited on the substrate SUB.

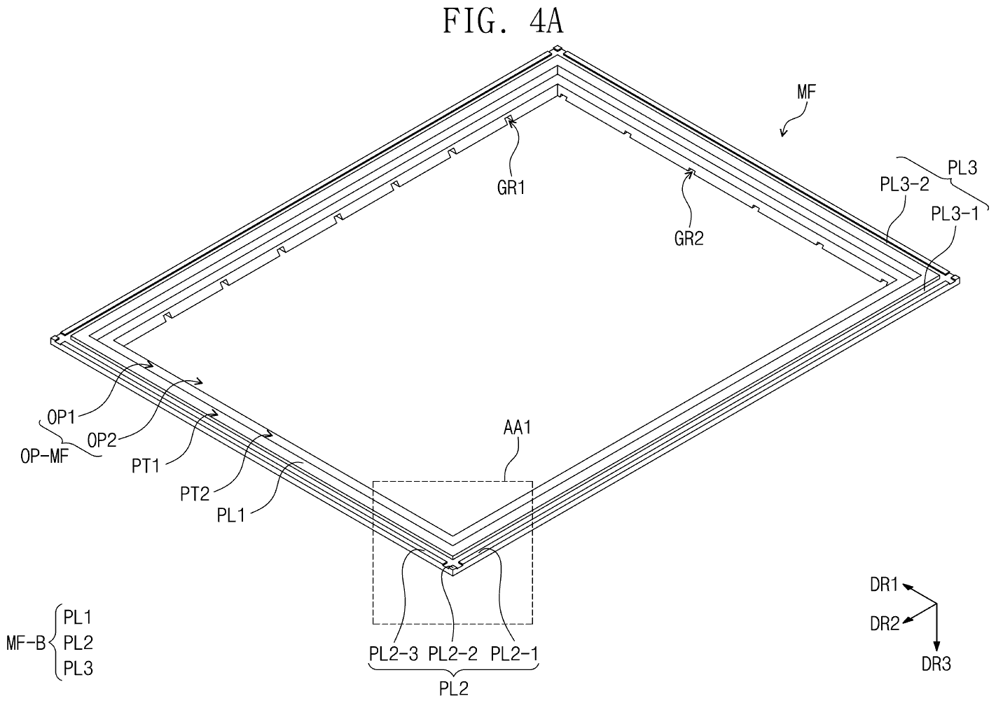

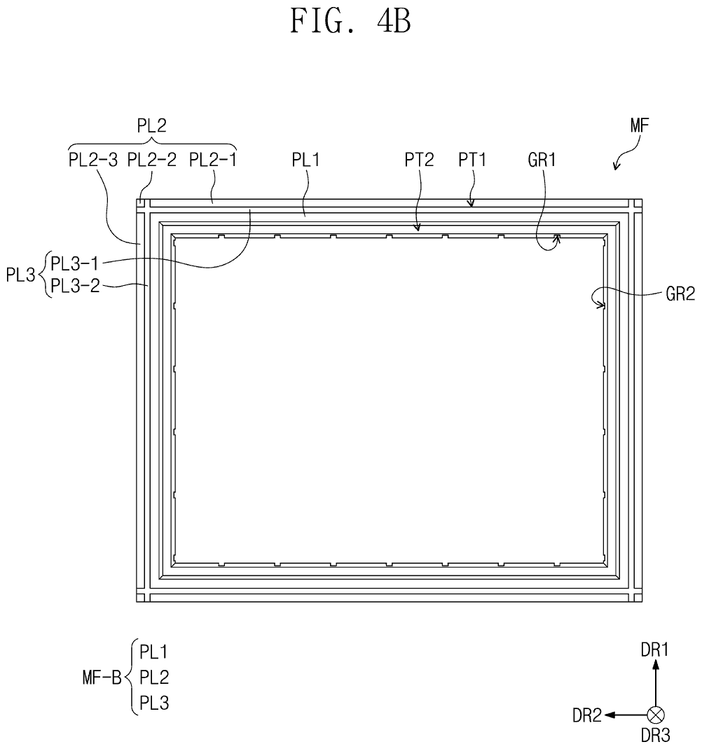

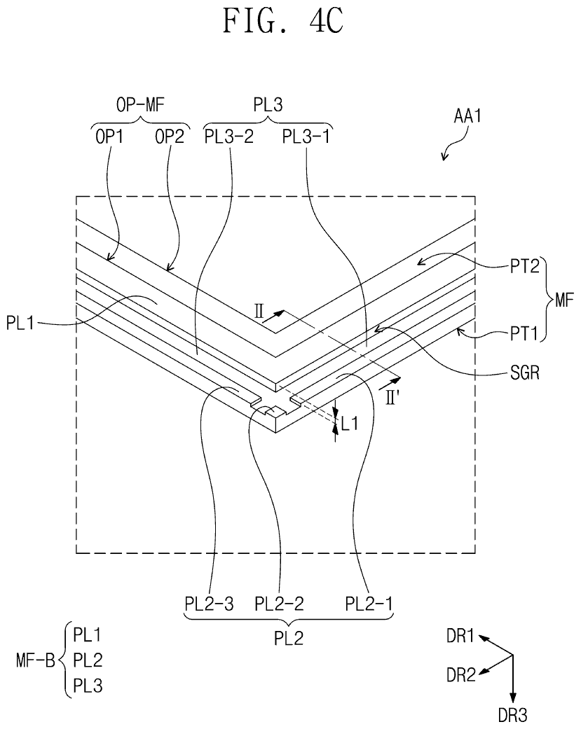

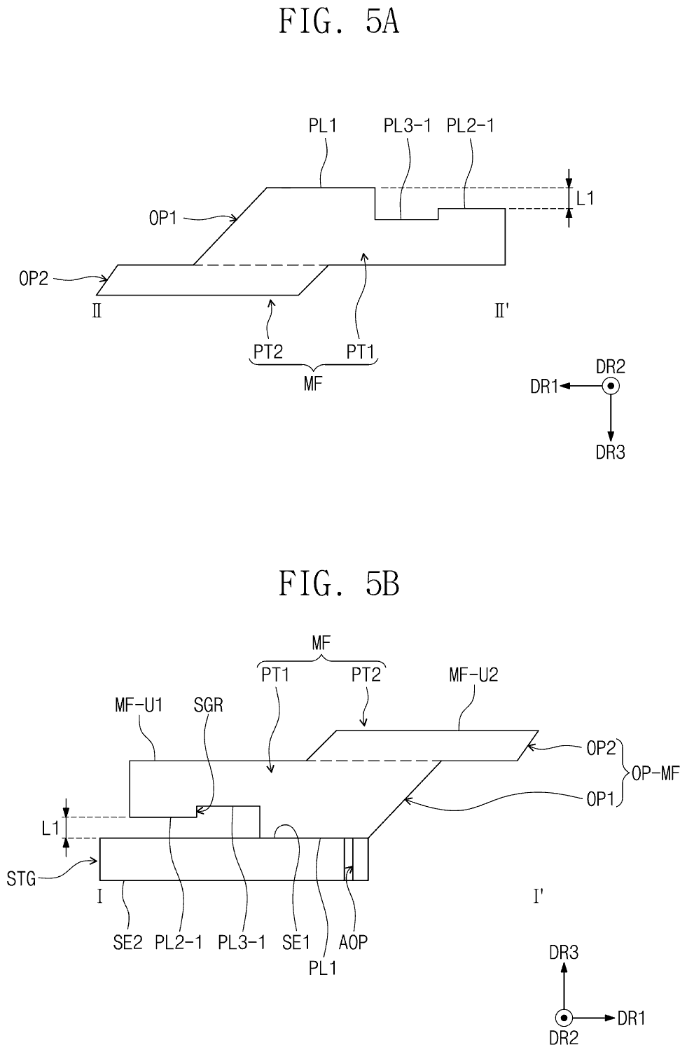

FIG. 3 schematically illustrates an orthographic view of a stage and a mask frame of the mask assembly in FIG. 2A according to some embodiments. FIG. 4A schematically illustrates a perspective view of the mask frame in FIG. 3 according to some embodiments. FIG. 4B schematically illustrates an orthographic view of a lower surface of the mask frame in FIG. 4A according to some embodiments. FIG. 4C schematically illustrates a perspective detail view of a first region AA1 in FIG. 4A according to some embodiments. FIG. 5A schematically illustrates a cross-sectional view of the mask assembly in FIG. 4C taken along sectional line II-II′ according to some embodiments. FIG. 5B schematically illustrates a cross-sectional view of the stage and the mask frame in FIG. 3 taken along sectional line I-I′ according to some embodiments.

By way of example, FIGS. 4A to 4C illustrate the mask frame MF shown in FIG. 3 in a vertically inverted orientation such that a lower surface of the mask frame MF faces upward.

By way of example, FIGS. 5A and 5B illustrate cross-sectional views of a (2-1)-th surface PL2-1 and a (3-1)-th surface PL3-1, but cross-sections of a (2-3)-th surface PL2-3 and a (3-2)-th surface PL3-2 may have a substantially same shape as the cross-sections of the (2-2)-th surface PL2-2 and the (3-1)-th surface PL3-1.

The first grooves GR1 and second grooves GR2 shown in FIGS. 3 and 4A-4C are the same as the first grooves GR1 and the second grooves GR2 depicted in FIG. 2B. As such, duplicate descriptions of these features will be omitted or made briefly.

Referring to FIGS. 3, 5A, and 5B, the mask frame MF may include a first portion PT1 and a second portion PT2. The second portion PT2 may be disposed on (and/or extend from) an upper surface MF-U1 of the first portion PT1. A side of the second portion PT2 opposing another side of the second portion PT2 in the first direction DR1 may protrude toward the frame opening OP-MF further than a side of the first portion PT1 opposing another side of the first portion PT1 in the first direction DR1. The side of the second portion PT2 is shown in FIG. 5A in association with second opening OP2, which is described later. A side of the first portion PT1 opposing another side of the first portion PT1 in the first direction DR1 may be an inner side bounding at least a portion of the frame opening OP-MF. The side of the first portion PT1 is shown in FIG. 5A in association with first opening OP1, which is described later. Similarly, the aforementioned side of the second portion PT2 may be an inner side bounding at least another portion of the frame opening OP-MF.

At least one side of the first portion PT1 may be an inclined surface. As shown in FIGS. 5A and 5B, only the side of the first portion PT1 is an inclined surface. The side and the other side of the second portion PT2 that oppose each other in the first direction DR1 may each be an inclined surface. The side of the first portion PT1 and the side of the second portion PT2 may each have an inclined surface, and to this end, once the deposition material EV (see FIG. 1) passes through the stage opening OP-ST, a portion of the deposition material EV may be deposited on the substrate SUB (see FIG. 1) according to a projection of the inclined surface of the side of the second portion PT2 on the substrate SUB.

The frame opening OP-MF may include a first opening OP1 and a second opening OP2. The side of the first portion PT1 may define or bound at least a portion of the first opening OP1. The side of the second portion PT2 may define or bound at least a portion of the second opening OP2. The first opening OP1 and the second opening OP2 may be continuously defined in a third direction DR3. For instance, the first opening OP1 may be fluidically connected with the second opening OP2 to enable the deposition material EV to flow through the frame opening OP-MF as part of at least one stage of deposition. An area of the first opening OP1 in a plane parallel to a plane defined by the first and second directions DR1 and DR2 may be greater than a corresponding area of the second opening OP2.

The first grooves GR1 and the second grooves GR2 may be formed in an upper surface MF-U2 of the second portion PT2. The first grooves GR1 may be arranged along the second direction DR2. The second grooves GR2 may be arranged along the first direction DR1. The first sticks ST1 (see FIG. 2B) may be at least partially disposed in the first grooves GR1. The second sticks ST2 (see FIG. 2B) may be at least partially disposed in the second grooves GR2.

Referring to FIGS. 3, 4A, and 4B, a lower surface MF-B of the first portion PT1 may include a first surface PL1, a second surface PL2, and a third surface PL3. The first surface PL1 may be defined as a lower surface of a portion corresponding to an inner edge of the first portion PT1 bounding at least a portion of the first opening OP1. The first surface PL1 may be adjacent to the first opening OP1. In a plan view, the first surface PL1 may surround the frame opening OP-MF. In a plan view, the first surface PL1 may surround the second portion PT2.

Referring to FIGS. 4B, 4C, 5A, and 5B, the second surface PL2 may be disposed further outwards (relative to the frame opening OP-MF) than the first surface PL1. The second surface PL2 may be defined as a lower surface corresponding to an outer edge of the mask frame MF. The second surface PL2 may include (2-1)-th surfaces PL2-1, (2-2)-th surfaces PL2-2, and (2-3)-th surfaces PL2-3.

Each of the (2-1)-th surfaces PL2-1 may be defined as a lower surface corresponding to an edge extending along long sides of the mask frame MF. The (2-1)-th surfaces PL2-1 may be adjacent to the long sides of the mask frame MF. The (2-1)-th surfaces PL2-1 may extend in the second direction DR2 along the long sides of the mask frame MF. The (2-1)-th surfaces PL2-1 may be disposed further outwards (relative to the frame opening OP-MF) than the first surface PL1.

As illustrated in FIGS. 4C and 5A, which depict the lower surface MF-B of the first portion PT1 facing upward, the (2-1)-th surfaces PL2-1 may be disposed lower than the first surface PL1 in the third direction DR3. By way of example, a first distance L1 defined as a difference between a height of each of the (2-1)-th surfaces PL2-1 and a height of the first surface PL1 may be about 0.05 mm to about 0.15 mm.

As illustrated in FIG. 5B, in a case that the lower surface MF-B of the first portion PT1 is disposed to face an upper surface of the stage STG, the (2-1)-th surfaces PL2-1 may be greater in height than the first surface PL1. Accordingly, the first surface PL1 may be disposed on the upper surface SE1 of the stage STG, and the (2-1)-th surfaces PL2-1 may be spaced apart from the upper surface SE1 of the stage STG by the first distance L1.

Referring to FIGS. 4A to 4C, each of the (2-2)-th surfaces PL2-2 may be defined as a lower surface of the first portion PT1 adjacent to corners of the mask frame MF. The (2-2)-th surfaces PL2-2 may be adjacent to the outside corners of the mask frame MF. The (2-2)-th surfaces PL2-2 may each be planar surface parallel to a plane defined by the first direction DR1 and the second direction DR2. By way of example, in a plan view, the (2-2)-th surfaces may each have a quadrangular shape, but embodiments are not limited thereto.

As illustrated in FIG. 4C, which depicts the lower surface MF-B of the first portion PT1 facing upward, a height of each of the (2-2)-th surfaces PL2-2 from the upper surface MF-U1 of the first portion PT1 may be substantially the same as a corresponding height of each of the (2-1)-th surfaces PL2-1. The (2-2)-th surfaces PL2-2 may be disposed lower than the first surface PL1. For instance, a difference between the height of each of the (2-2)-th surfaces PL2-2 and the height of the first surface PL1 may be about 0.05 mm to about 0.15 mm.

Although not illustrated, in a case that the lower surface MF-B of the first portion PT1 faces the upper surface SE1 of the stage STG, the (2-2)-th surfaces PL2-2 may be greater in height than the first surface PL1. For instance, the (2-2)-th surfaces PL2-2 may be further away from the upper surface SE1 of the stage STG in the third direction DR3 than the first surface PL1. Accordingly, the first surface PL1 may be disposed on the upper surface SE1 of the stage STG, and the (2-2)-th surfaces PL2-2 may be spaced apart from the upper surface SE1 of the stage STG by, for instance, the first distance L1.

Each of the (2-3)-th surfaces PL2-3 may be defined as a lower surface corresponding to an edge extending along short sides of the mask frame MF. The (2-3)-th surfaces PL2-3 may be adjacent to the short sides of the mask frame MF. The (2-3)-th surfaces PL2-3 may extend in the first direction DR1 along the short sides of the mask frame MF. The (2-3)-th surfaces PL2-3 may be disposed further outwards (relative to the frame opening OP-MF) than the first surface PL1.

As illustrated in FIG. 4C, which depicts the lower surface MF-B of the first portion PT1 facing upward, the (2-3)-th surfaces PL2-3 may be disposed lower than the first surface PL1. A height of each of the (2-3)-th surfaces PL2-3 from the upper surface MR-U1 of first part PT1 may be substantially the same as the corresponding heights of the (2-1)-th surfaces PL2-1 and the (2-2)-th surfaces PL2-2. For instance, a difference between the height of each of the (2-3)-th surfaces PL2-3 and the height of the first surface PL1 in the third direction DR3 may be about 0.05 mm to about 0.15 mm.

Although not illustrated, in a case that the lower surface MF-B of the first portion PT1 faces the upper surface SE1 of the stage STG, the (2-3)-th surfaces PL2-3 may be greater in height than the first surface PL1. For instance, the (2-3)-th surfaces PL2-3 may be further away from the upper surface SE1 of the stage STG in the third direction DR3 than the first surface PL1. Accordingly, the first surface PL1 may be disposed on the upper surface SE1 of the stage STG, and the (2-3)-th surfaces PL2-3 may be spaced apart from the upper surface SE1 of the stage STG by, for instance, the first distance L1.

Referring to FIGS. 2A, 2B, 4C, and 5B, in a case that the masks MK are stretched, the masks MK may have a property of returning to a shape before being stretched, e.g., the masks MF may be elastically deformed in response to being stretched. As such, the masks MK may have a property of being restored in a direction opposite to a direction in which the masks MK are stretched in response to an applied stretching force being removed.

The masks MK connected to the mask frame MF may apply restoring force to the mask frame MF. Accordingly, the mask frame MF may be deformed. By way of example, the long sides of the mask frame MF may be bent concavely toward the frame opening OP-MF. The deformed mask frame MF may have a property of being restored to a shape before deformation, e.g., the mask frame MF may be elastically deformed in response to the restoring force applied to the mask frame MF by the masks MK.

In a case that the mask frame MF is restored, frictional force may be generated between the upper surface SE1 of the stage STG and the lower surface of the mask frame MF, such as the first surface PL1 of the mask frame MF. The frictional force may be proportional to a contact area between the upper surface SE1 of the stage STG and the lower surface of the mask frame MF, e.g., the first surface PL1 of the mask frame MF. A direction of the frictional force acting on the mask frame MF and a direction in which the mask frame MF is restored may be opposite each other.

As the contact area between the lower surface of the mask frame MF and the upper surface SE1 of the stage STG increases, the frictional force acting between the lower surface of the mask frame MF and the upper surface SE1 of the stage STG may become relatively large, and as such, the mask frame MF may not be completely restored to its shape before deformation. Accordingly, the masks MK connected to the mask frame MF may not maintain a stretched state, and respective shapes of the mask openings OP-MK in the cell regions CEA may be deformed. This may cause, at least in part, one or more defects to occur in a case that the deposition material EV (see FIG. 1) is deposited on the substrate SUB (see FIG. 1).

However, according to some embodiments including the mask frame MF being disposed on the stage STG, a height of the second surface PL2 may be greater than a height of the first surface PL1. For example, there may be a step between the first surface PL1 and the second surface PL2.

Since the height of the second surface PL2 may be greater than the height of the first surface PL1, the first surface PL1 may be disposed on the upper surface SE1 of the stage STG, and the second surface PL2 may be spaced apart from the upper surface SE1 of the stage STG. As such, the contact area between the upper surface SE1 of the stage STG and the lower surface (e.g., first surface PL1) of the mask frame MF may be reduced. Accordingly, frictional force generated between the upper surface SE1 of the stage STG and the lower surface (e.g., first surface PL1) of the mask frame MF may be reduced, and the mask frame MF may thus be readily restored to its original shape. Thus, the masks MK connected to the mask frame MF may maintain a stretched state, thereby preventing or at least reducing the likelihood of one or more defects occurring in a case that the deposition material EV (see FIG. 1) is deposited on the substrate SUB (see FIG. 1).

Referring to FIGS. 4B to 5B, in a plan view, the third surface PL3 may surround the first surface PL1. The third surface PL3 may be disposed further outwards (relative to frame opening OP-MF) than the first surface PL1. The third surface PL3 may be disposed further inwards (relative to frame opening OP-MF) than the second surface PL2. For instance, the third surface PL3 may be disposed between the first surface PL1 and the second surface PL2.

As illustrated in FIG. 4C, a stick groove SGR may be defined in the lower surface MF-B of the first portion PT1. In some embodiments, the mask assembly MSA (FIG. 2B) may further include an auxiliary stick, and the auxiliary stick may be at least partially disposed in the stick groove SGR.

The third surface PL3 may be defined as a bottom surface of the stick groove SGR. Auxiliary sticks may be disposed between the third surface PL3 and the upper surface SE1 of the stage STG. The auxiliary sticks may be omitted.

As illustrated in FIG. 5A, in a case that the lower surface MF-B of the first portion PT1 is disposed to face upward, the third surface PL3 may be disposed lower than the second surface PL2 relative to first surface PL1. Although not illustrated, in a case that the lower surface MF-B of the first portion PT1 faces the upper surface SE1 of the stage STG, a height of the third surface PL3 may be greater than the height of the second surface PL2 in terms of a distance from the upper surface SE1 of the stage STG.

The third surface PL3 may include (3-1)-th surfaces PL3-1 and (3-2)-th surfaces PL3-2. The (3-1)-th surfaces PL3-1 may be disposed between the first surface PL1 and the (2-1)-th surfaces PL2-1 in the first direction DR1.

The (3-1)-th surfaces PL3-1 may extend in the second direction DR2 along the long sides of the mask frame MF. The (3-1)-th surfaces PL3-1 may extend from a first side of the mask frame MF to a second side of the mask frame MF, the first and second sides may oppose each other in the second direction DR2. In a plan view, the (3-1)-th surfaces PL3-1 may be disposed between the first surface PL1 and the (2-1)-th surfaces PL2-1. In a plan view, opposing ends of each of the (3-1)-th surfaces PL3-1 opposing each other in the second direction DR2 may pass between the (2-2)-th surfaces PL2-2 and the (2-3)-th surfaces PL2-3.

The (3-2)-th surfaces PL3-2 may extend in the first direction DR1 along the short sides of the mask frame MF. The (3-2)-th surfaces PL3-2 may extend from a third side of the mask frame MF to a fourth side of the mask frame MF, the first and second sides opposing each other in the first direction DR1. In a plan view, the (3-2)-th surfaces PL3-2 may be disposed between the first surface PL1 and the (2-3)-th surfaces PL2-3 in the second direction DR2. Opposing ends of each of the (3-2)-th surfaces PL3-2 opposing each other in the first direction DR1 may pass between the (2-1)-th surfaces PL2-1 and the (2-2)-th surfaces PL2-2. In a plan view, the (3-1)-th surfaces PL3-1 and the (3-2)-th surfaces PL3-2 may cross each other.

Referring to FIG. 5B, the stage STG may be disposed on the lower surface (e.g., first surface PL1) of the mask frame MF. A pneumatic opening AOP may be defined in the stage STG according to some embodiments. The pneumatic opening AOP may overlap the first surface PL1 in the third direction DR3.

Although not illustrated, air may be introduced into the pneumatic opening AOP by an external device connected to the stage STG. The air introduced through the pneumatic opening AOP may be blown toward the mask frame MF. The air may apply pressure to the first surface PL1 in a third direction DR3. The pressure of the air may be applied in a direction opposite to a direction of gravity on the mask frame MF. Accordingly, frictional force generated between the stage STG and the mask frame MF may be reduced. However, this is an example, and according to some embodiments, the pneumatic opening AOP may be omitted.

Although not illustrated, air may flow between the second surface PL2 and the upper surface SE1 of the stage STG since the second surface PL2 may be spaced apart from the upper surface SE1 of the stage STG. Accordingly, the air may also apply pressure to the second surface PL2.

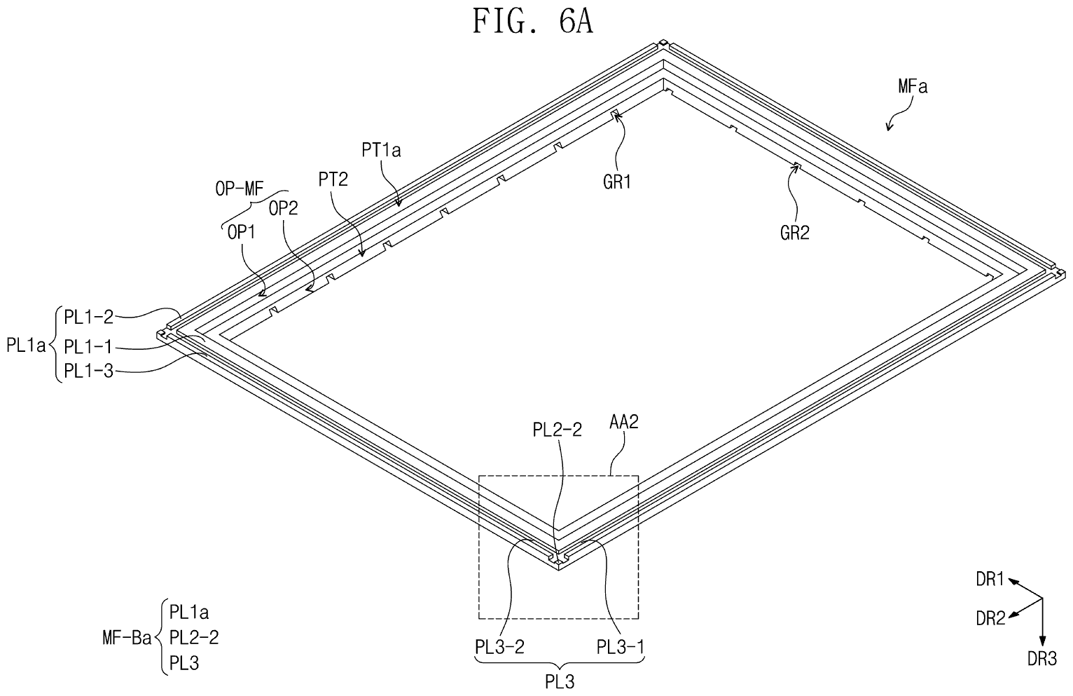

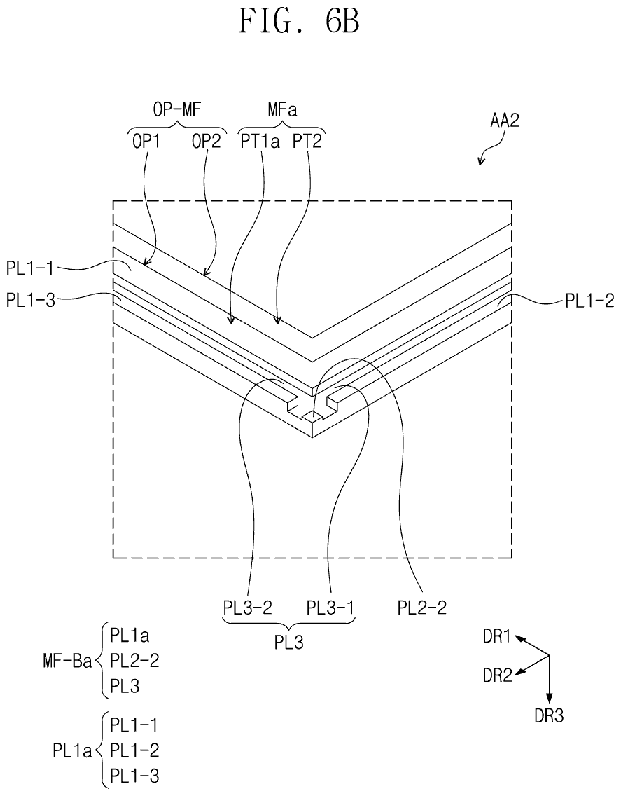

FIGS. 6A and 6B schematically illustrate a perspective view and a partial perspective detail view of a lower surface of a mask frame according to some embodiments. By way of example, FIG. 6B is an enlarged perspective view of a second region AA2 in FIG. 6A.

By way of example, FIGS. 6A and 6B illustrate a mask frame MFa in a vertically inverted orientation such that a lower surface (e.g., first surface PL1a) of the mask frame MFa faces upward.

Since a third surface PL3, a (2-2)-th surface PL2-2, a frame opening OP-MF, a second portion PT2, first grooves GR1, and second grooves GR2 in FIGS. 6A and 6B are the same as the third surface PL3, the (2-2)-th surface PL2-2, the frame opening OP-MF, and the second portion PT2 in FIG. 4C and the first grooves GR1 and the second grooves GR2 in FIG. 3, duplicative descriptions will be omitted or made briefly.

Referring to FIGS. 6A and 6B, a lower surface MF-Ba of a first portion PT1a may include a first surface PL1a, (2-2)-th surfaces PL2-2, and the third surface PL3. The first surface PL1a may include a (1-1)-th surface PL1-1, (1-2)-th surfaces PL1-2, and (1-3)-th surfaces PL1-3.

The (1-1)-th surface PL1-1 may be adjacent to a first opening OP1 forming or at least partially bounding a portion of frame opening OP-MF. The (1-1)-th surface PL1-1 may be defined as a lower surface of a portion corresponding to an inner edge of the first portion PT1a defining (or at least partially bounding) the first opening OP1.

The (1-1)-th surface PL1-1 may be adjacent to a first opening OP1. The (1-1)-th surface PL1-1 may be defined as a lower surface of a portion corresponding to an inner edge of the first portion PT1a defining (or at least partially bounding) the first opening OP1. In a plan view, the (1-1)-th surface PL1-1 may surround the second portion PT2. In a plan view, the (1-1)-th surface PL1-1 may surround the first opening OP1.

The (1-2)-th surfaces PL1-2 may be adjacent to long sides of the mask frame MFa. The (1-2)-th surfaces PL1-2 may be defined as a lower surface corresponding to an edge of the first portion PT1a extending along the long sides of the mask frame MFa. The (1-2)-th surfaces PL1-2 may extend in a second direction DR2 along the long sides of the mask frame MFa.

The (1-3)-th surfaces PL1-3 may be adjacent to short sides of the mask frame MFa. The (1-3)-th surfaces PL1-3 may be defined as a lower surface corresponding to an edge of the first portion PT1a extending along the short sides of the mask frame MFa. The (1-3)-th surfaces PL1-3 may extend in a first direction DR1 along the short sides of the mask frame MFa.

The (1-1)-th surface PL1-1, the (1-2)-th surfaces PL1-2, and the (1-3)-th surfaces PL1-3 may have a same height relative to the upper surface MF-U1 of the mask frame MFa. Although not illustrated, in a case that the mask frame MFa is disposed on the upper surface SE1 of the stage STG in FIGS. 2A and 2B, the (1-1)-th surface PL1-1, the (1-2)-th surfaces PL1-2, and the (1-3)-th surfaces PL1-3 may be disposed on the upper surface SE1 of the stage STG.

The (2-2)-th surfaces PL2-2 may be defined as a lower surface of the first portion PT1a adjacent to corners of the mask frame MFa. The (2-2)-th surfaces PL2-2 may be adjacent to the corners of the mask frame MFa.

As illustrated in FIG. 6B, in a case that the lower surface MF-Ba of the first portion PT1a is disposed to face upward, the (2-2)-th surfaces PL2-2 may be disposed lower than the first surface PL1a relative to the upper surface MF-U1 of the mask frame MFa. In a case that the lower surface MF-Ba of the first portion PT1a is disposed on the upper surface SE1 of the stage STG (see FIGS. 2A and 2B), the (2-2)-th surfaces PL2-2 may be greater in height than the first surface PL1a relative to a distance from the upper surface SE1 of the stage STG. Accordingly, the first surface PL1a may be disposed on the upper surface SE1 of the stage STG (see FIGS. 2A and 2B), and the (2-2)-th surfaces PL2-2 may be spaced apart from the upper surface SE1 of the stage STG (see FIG. 2B).

In a case that the mask frame MFa, which may be deformed by the masks MK (see FIGS. 2A and 2B) is restored to a shape before deformation, frictional force may be generated between the lower surface of the mask frame MFa and the upper surface SE1 of the stage STG (see FIGS. 2A and 2B). The frictional force may be largest at a lower surface of a portion adjacent to the corner of the mask frame MFa, e.g., in portions corresponding to (2-2)-th surfaces PL2-2.

Since the (2-2)-th surfaces PL2-2 may be adjacent to the corners of the mask frame MFa, the corners of the mask frame MFa and the upper surface SE1 of the stage STG (see FIGS. 2A and 2B) may be spaced apart from each other. Accordingly, the frictional force generated between the lower surface of the mask frame MFa and the upper surface SE1 of the stage STG (see FIGS. 2A and 2B) may be reduced. Thus, the mask frame MFa may be readily restored, and a defect may be prevented (or at least mitigated) from occurring in a case that the deposition material EV (see FIG. 1) is deposited on the substrate SUB (see FIG. 1).

The (3-1)-th surfaces PL3-1 may be disposed between the (1-1)-th surface PL1-1 and the (1-2)-th surfaces PL1-2 in the first direction DR1. Opposing ends of each of the (3-1)-th surfaces PL3-1 opposing each other in the second direction DR2 may be disposed between the (2-2)-th surfaces PL2-2 and the (1-3)-th surfaces PL1-3.

The (3-2)-th surfaces PL3-2 may be disposed between the (1-1)-th surface PL1-1 and the (1-3)-th surfaces PL1-3 in the second direction DR2. Opposing ends of each of the (3-2)-th surfaces PL3-2 opposing each other in the first direction DR1 may be disposed between the (2-2)-th surfaces PL2-2 and the (1-2)-th surfaces PL1-2.

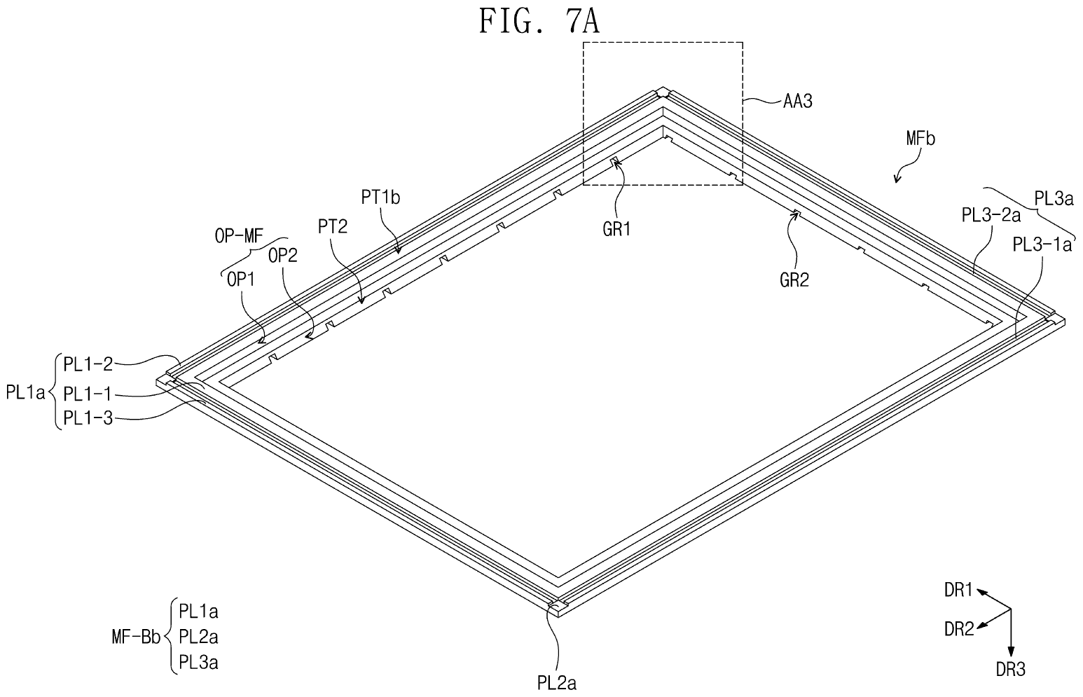

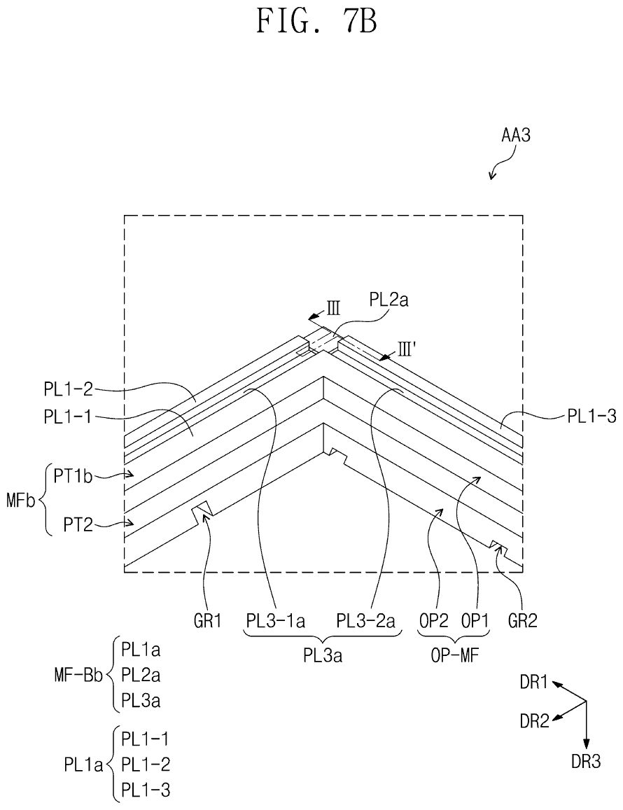

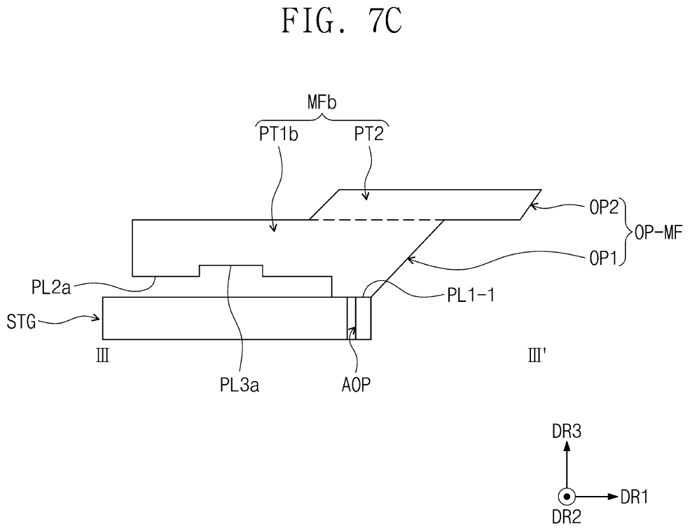

FIGS. 7A, 7B, and 7C schematically illustrate a perspective view, a partial perspective detail view, and a cross-sectional view of a mask frame according to some embodiments. By way of example, FIG. 7B is an enlarged perspective view of a third region AA3 in FIG. 7A, and FIG. 7C is a cross-sectional view of a mask frame MFb disposed on the stage STG (see FIGS. 2A and 2B) in which a cross section of the mask frame MFb is taken along sectional line III-III′ according to some embodiments.

By way of example, FIGS. 7A and 7B illustrate a mask frame MFb in a vertically inverted orientation such that a lower surface MF-Bb of the mask frame MFb faces upward.

Since a (1-1)-th surface PL1-1, a (1-2)-th surface PL1-2, a (1-3)-th surface PL1-3, a second portion PT2, a frame opening OP-MF, and a stage STG in FIGS. 7A to 7C are the same as the (1-1)-th surface PL1-1, the (1-2)-th surface PL1-2, the (1-3)-th surface PL1-3, the second portion PT2, the frame opening OP-MF in FIG. 6B and the stage STG in FIG. 2A, duplicative descriptions will be omitted or made briefly.

Referring to FIGS. 7A to 7C, a lower surface MF-Bb of a first portion PT1b may include a first surface PL1a, second surfaces PL2a, and a third surface PL3a.

Since the first surface PL1a is substantially the same as the first surface PL1a in FIG. 6B, duplicative description of the first surface PL1a will be omitted.

The second surfaces PL2a may be adjacent to corners of the mask frame MFb. The second surface PL2a may be defined as a lower surface of the first portion PT1b adjacent to the corners of the mask frame MFb.

As illustrated in FIG. 7B, in a case that the lower surface MF-Bb of the first portion PT1b is disposed to face upward, the second surfaces PL2a may be smaller in height than the first surface PL1a relative to the upper surface MF-U1 of the mask frame MFb. As illustrated in FIG. 7C, in a case that the mask frame MFb is disposed on the stage STG, the second surfaces PL2a may be greater in height than the (1-1)-th surface PL1-1, e.g., the second surfaces PL2a may be disposed further away from the upper surface SE1 of the stage STG than the (1-1)-th surface PL1-1. Accordingly, the second surfaces PL2a may not be in contact with the upper surface SE1 of the stage STG.

The third surface PL3a may include (3-1)-th surfaces PL3-1a and (3-2)-th surfaces PL3-2a. The (3-1)-th surfaces PL3-1a may be disposed between the (1-1)-th surface PL1-1 and the (1-2)-th surfaces PL1-2 in the first direction DR1. The (3-1)-th surfaces PL3-1a may be disposed between the second surfaces PL2a adjacent to each other in the second direction DR2. In a plan view, the (3-1)-th surfaces PL3-1a may extend in the second direction DR2 between the second surfaces PL2a adjacent to each other in the second direction DR2. A sum of a length of the (3-1)-th surfaces PL3-1a in the first direction DR1 and a length of the (1-2)-th surfaces PL1-2 in the first direction DR1 may be the same as a length of the second surfaces PL2a in the first direction DR1, but embodiments are not limited thereto.

The (3-2)-th surfaces PL3-2a may be disposed between the (1-1)-th surface PL1-1 and the (1-3)-th surfaces PL1-3 in the second direction DR2. The (3-2)-th surfaces PL3-2a may be disposed between the second surfaces PL2a adjacent to each other in the first direction DR1. In a plan view, the (3-2)-th surfaces PL3-2a may extend in the first direction DR1 between the second surfaces PL2a adjacent to each other in the first direction DR1. A sum of a length of the (3-2)-th surfaces PL3-2a in the second direction DR2 and a length of the (1-3)-th surfaces PL1-3 in the second direction DR2 may be the same as a length of the second surfaces PL2a in the second direction DR2, but embodiments are not limited thereto.

For example, in a case that the second surface PL2a in FIG. 7B is compared to the (2-2)-th surface PL2-2 in FIG. 6B, an area (e.g., planar surface area) of the second surface PL2a in FIG. 7B may be greater than a corresponding area of the (2-2)-th surface PL2-2 in FIG. 6B.

Since the second surfaces PL2a may not be in contact with the upper surface SE1 of the stage STG (see FIG. 7C), frictional force generated between the lower surface of the mask frame MFb and the upper surface SE1 of the stage STG (see FIG. 7C) may be reduced. Accordingly, the mask frame MFb, which may be deformed by the masks MK (see FIGS. 2A and 2B) may be readily restored. Thus, a defect may be prevented (or at least mitigated) from occurring in a case that the deposition material EV (see FIG. 1) is deposited on the substrate SUB (see FIG. 1).

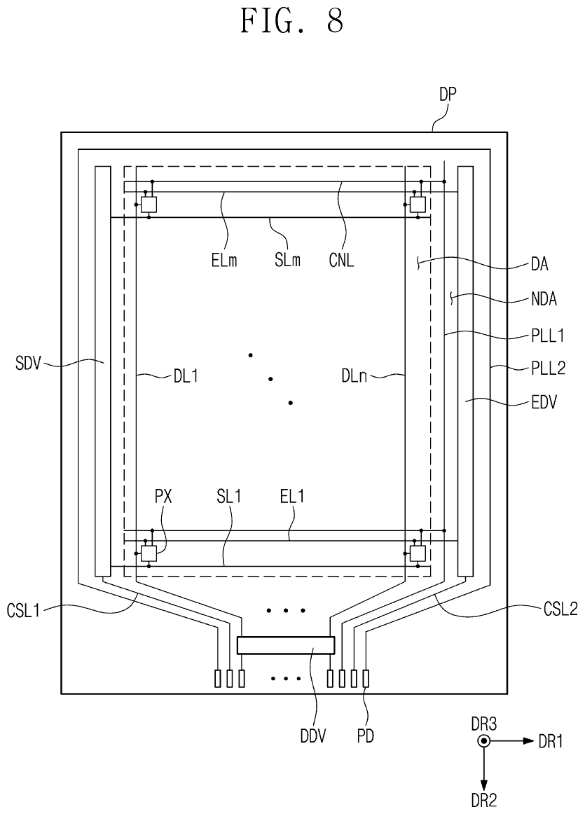

FIG. 8 schematically illustrates an orthographic view of a display panel manufactured using the mask assembly described in association with FIG. 2A according to some embodiments.

Referring to FIG. 8, a display panel DP may have a rectangular shape having short sides extending in a first direction DR1 and long sides extending in a second direction DR2, but a shape of the display panel DP is not limited thereto. The display panel DP may include a display part DA and a non-display part NDA surrounding (or at least disposed outside of) the display part DA. The display part DA may be a region in which images may be displayed, and the non-display part NDA may be a region in which images are not displayed.

The display panel DP may be an emissive display panel. The display panel DP may be an organic light-emitting display panel or a quantum dot light-emitting display panel, but embodiments are not limited thereto. A light-emitting layer of the organic light-emitting display panel may include an organic light-emitting material. A light-emitting layer of the quantum dot light-emitting display panel may include quantum dots, quantum rods, etc. Hereinafter, the display panel DP will be described as an organic light-emitting display panel.

The display panel DP may include pixels PX, scan lines SL1 to SLm, data lines DL1 to DLn, emission lines EL1 to ELm, first and second control lines CSL1 and CSL2, first and second power lines PLL1 and PLL2, connection lines CNL, and pads PD. It is noted that “m” and “n” are natural numbers greater than or equal to 2.

The pixels PX may be disposed in the display part DA. A scan driver SDV and an emission driver EDV may be disposed in sections of the non-display part NDA respectively adjacent to the long sides of the display panel DP. A data driver DDV may be disposed in the non-display part NDA adjacent to any one short side among the short sides of the display panel DP. In a plan view, the data driver DDV may be adjacent to a lower end of the display panel DP in some implementations.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in the first direction DR1 and may be connected to the pixels PX and the emission driver EDV.

The first power line PLL1 may extend in the second direction DR2 and may be disposed in the non-display part NDA. The first power line PLL1 may be disposed between the display part DA and the emission driver EDV, but embodiments are not limited thereto. For instance, the first power line PLL1 may be disposed between the display part DA and the scan driver SDV.

The connection lines CNL may extend in the first direction DR1 and may be arranged in the second direction DR2. The connection lines CNL may be connected to the first power line PLL1 and the pixels PX. A first voltage may be applied to the pixels PX through the connection lines CNL and the first power line PLL1 connected to each other.

The second power line PLL2 may be disposed in the non-display part NDA. The second power line PLL2 may extend along the long sides of the display panel DP and another short side of the display panel DP around which the data driver DDV is not disposed. The second power line PLL2 may be disposed on a further outward side than the scan driver SDV and the emission driver EDV. For instance, the second power line PLL2 may at least partially surround the scan driver SDV and the emission driver EDV in a plan view.

Although not illustrated, the second power line PLL2 may extend toward the display part DA and may be connected to the pixels PX. A second voltage having a lower level than the first voltage may be applied to the pixels PX through the second power line PLL2. In some cases, the second voltage may correspond to ground or have a zero potential voltage.

The first control line CSL1 may be connected to the scan driver SDV, and in a plan view, may extend toward the lower end of the display panel DP. The second control line CSL2 may be connected to the emission driver EDV, and in a plan view, may extend toward the lower end of the display panel DP. The data driver DDV may be disposed between the first control line CSL1 and the second control line CSL2.

The pads PD may be disposed on the display panel DP in the non-display part NDA. The pads PD may be more adjacent to the lower end of the display panel DP than the data driver DDV, but embodiments are not limited thereto. The data driver DDV, the first power line PLL1, the second power line PLL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Light-emitting elements of the display panel DP may be formed in association with the cell regions CEA in FIGS. 2A and 2B.

Unit regions corresponding to such a display panel DP may be defined on the substrate SUB described above. In some instances, after the light-emitting elements are formed in the unit regions, the unit regions may be cut. Thus, the display panel DP in FIG. 8 may be manufactured.

Although not illustrated, a timing controller for controlling an operation of the scan driver SDV, the data driver DDV, and the emission driver EDV, and a voltage generator for generating the first and second voltages may be disposed on a printed circuit board, which may be electrically connected to one or more portions of the display panel PD. The timing controller and the voltage generator may be connected to (e.g., electrically and physically connected to) corresponding pads PD through the printed circuit board.

The scan driver SDV may generate scan signals, and the scan signals may be applied to the pixels PX through the scan lines SL1 to SLm. The data driver DDV may generate data voltages, and the data voltages may be applied to the pixels PX through the data lines DL1 to DLn. The emission driver EDV may generate emission signals, and the emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. An emission time of the pixels PX may be controlled by the emission signals.

Lines described above may include the data lines DL1 to DLn. Pads connected to the lines described above may include the pads PD in FIG. 8. The display panel DP in which light-emitting layers of the pixels PX are not yet formed may be defined as the substrate SUB described above.

The pads PD may be formed on the substrate SUB, and the substrate SUB may be defined as being in a state in which a printed circuit board is not connected. The pads PD may be connected to a ground terminal, and the pads PD and the data lines DL1 to DLn may be grounded.

FIG. 9 schematically illustrates a cross-sectional view of a representative pixel in FIG. 8 according to some embodiments.

Referring to FIGS. 8 and 9, the pixel PX may be disposed on a base substrate BS and include a transistor TR and a light-emitting element OLED. Transistors TR and light-emitting elements OLED of the pixels PX may be electrically connected to the first and second power lines PLL1 and PLL2 and the data lines DL1 to DLn described above.

The transistors TR and the light-emitting elements OLED of the pixels PX may be electrically connected to the pads PD in FIG. 8 through the data lines DL1 to DLn (see FIG. 8) and the first and second power lines PLL1 and PLL2 (see FIG. 8).

The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode, or vice versa.

The transistor TR and the light-emitting element OLED may be disposed on the base substrate BS. A single transistor TR is illustrated as an example, but substantially, the pixel PX may include transistors and at least one capacitor for driving the light-emitting element OLED.

A display part DA may include a light-emitting part PA corresponding to the pixel PX and a non-light-emitting part NPA around the light-emitting part PA. The light-emitting element OLED may be at least disposed in the light-emitting part PA.

The base substrate BS may include a flexible plastic substrate. For example, the base substrate BS may include transparent polyimide (PI), but embodiments are not limited thereto. A buffer layer BFL may be disposed on the base substrate BS, and the buffer layer BFL may be or include an inorganic layer.

A semiconductor pattern may be disposed on the buffer layer BFL. The semiconductor pattern may include polysilicon. However, embodiments are not limited thereto. For instance, the semiconductor pattern may include amorphous silicon or a metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may substantially serve as a source electrode and a drain electrode of the transistor TR. The lightly doped region may substantially correspond to an active (or channel) region of the transistor.

A source region S, an active region A, and a drain region D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light-emitting element OLED and electrically connect the transistor TR and the light-emitting element OLED. The connection electrode CNE may include a first connection electrode CNE1 and a second connection electrode CNE2.

The first connection electrode CNE1 may be disposed on the third insulating layer INS3 and connected to the drain region D through a first contact hole CH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in the fifth insulating layer INS5. A sixth insulating layer INS6 may be disposed on the second connection electrode CNE2. Each of the first insulating layer INS1 to the sixth insulating layer INS6 may be an inorganic layer and/or an organic layer.

The first electrode AE may be disposed on the sixth insulating layer INS6. The first electrode AE may be electrically connected to the second connection electrode CNE2 through a third contact hole CH3 defined in the sixth insulating layer INS6. A pixel-defining film PDL, which exposes a portion of the first electrode AE, may be disposed on the first electrode AE and the sixth insulating layer INS6. An opening PX_OP exposing the portion of the first electrode AE may be defined in the pixel-defining film PDL.

The hole control layer HCL may be disposed on the first electrode AE and the pixel-defining film PDL. The hole control layer HCL may be disposed in common in the light-emitting part PA and the non-light-emitting part NPA. The hole control layer HCL may include a hole transport layer and a hole injection layer.

The light-emitting layer EML may be disposed on the hole control layer HCL. The light-emitting layer EML may be disposed in a region corresponding to the opening PX_OP. As seen in FIG. 9, the light-emitting layer EML may extend into a portion of the non-light emitting part NPA. The light-emitting layer EML may include an organic material and/or an inorganic material. The light-emitting layer EML may generate light having any one color among red, green, and blue, but embodiments are not limited thereto. For instance, the light-emitting layer EML may be configured to emit white light.

The electron control layer ECL may be disposed on the light-emitting layer EML and the hole control layer HCL. The electron control layer ECL may be disposed in common in the light-emitting part PA and the non-light-emitting part NPA. The electron control layer ECL may include an electron transport layer and an electron injection layer.

The second electrode CE may be disposed on the electron control layer ECL. The second electrode CE may be disposed in common in the pixels PX.

A thin-film encapsulation layer TFE may be disposed on the light-emitting element OLED. The thin-film encapsulation layer TFE may be disposed on the second electrode CE and cover the pixel PX. The thin-film encapsulation layer TFE may include at least two inorganic layers and an organic layer between the inorganic layers. The inorganic layer may protect the pixel PX from moisture, oxygen, and/or the like. The organic layer may protect the pixel PX from foreign substances, such as dust particles, etc.

A first voltage may be applied to the first electrode AE through the transistor TR, and a second voltage having a lower level than the first voltage may be applied to the second electrode CE. A hole and an electron injected into the light-emitting layer EML may combine to form an exciton, and as the exciton transitions to a ground state, the light-emitting element OLED may emit light.

FIG. 10 schematically illustrates a cross-sectional view of the display panel in FIG. 8 during a stage of the deposition process in FIG. 1 according to some embodiments.

For convenience of description, FIG. 10 illustrates that the substrate SUB and the mask MK in FIG. 1 are rotated in a clockwise direction by about 90 degrees. For instance, the substrate SUB and the mask MK are shown in a horizontal orientation in FIG. 10 versus a vertical orientation as in FIG. 1.

Referring to FIGS. 1, 8, and 10, a base layer BS to a layer on which a first electrode AE is disposed may be defined as the substrate SUB described in association with at least FIG. 1. As described above, a transistor TR may be electrically connected to the pads PD through the data lines DL1 to DLn. For instance, the substrate SUB may include the data lines DL1 to DLn defined by the lines described above in association with FIG. 8 and the pads PD electrically connected to the data lines DL1 to DLn.

The mask MK may be disposed to face the substrate SUB. The mask MK may be disposed close to the substrate SUB. In some cases, the mask MF may be spaced apart from the substrate SUB to avoid direct contact between the mask MF and the substrate SUB. The deposition material EV may be provided (or deposited) on the substrate SUB through the mask opening OP-MK defined in an upper surface of the mask MK. A light-emitting layer EML may be formed on the substrate SUB by the deposition of the deposition material EV.

According to some embodiments, a lower surface of a mask frame may include a first surface surrounding a frame opening defined in the mask frame and a second surface adjacent to an edge of the mask frame. The first surface may be disposed on an upper surface of a stage, and the second surface may be spaced apart from the upper surface of the stage. Accordingly, a contact area between the lower surface of the mask frame and the upper surface of the stage may be reduced. Thus, in a case that the mask frame is deformed by a mask and then restored to its original shape, frictional force generated between the lower surface of the mask frame and the upper surface of the stage may be reduced, and the mask frame may thus be readily restored to its original shape.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A mask assembly comprising:
a stage;
a mask frame disposed on an upper surface of the stage, the mask frame comprising a frame opening bounded on first sides extending in a first direction and second sides extending in a second direction transverse to the first direction; and
a mask disposed on an upper surface of the mask frame, wherein:
a lower surface of the mask frame comprises:
a first surface surrounding the frame opening in a plan view; and
a second surface adjacent to at least one corner among corners of the mask frame in the plan view,
the first surface is disposed on the upper surface of the stage, and
the second surface is spaced apart from the upper surface of the stage in a third direction transverse to both the first direction and the second direction.

2. The mask assembly of claim 1, wherein a first distance between the second surface and the upper surface of the stage in the third direction is greater than a second distance between the first surface and the upper surface of the stage in the third direction.

3. The mask assembly of claim 2, wherein a difference between the first and second distances is in a range of about 0.05 mm to about 0.15 mm.

4. The mask assembly of claim 2, wherein:
the lower surface of the mask frame further comprises a third surface, the third surface comprising a (3-1)-th surface extending in the second direction and a (3-2)-th surface extending in the first direction, and
a fourth distance between the third surface and the upper surface of the stage in the third direction is greater than the first distance.

5. The mask assembly of claim 4, wherein the second surface comprises:
a (2-1)-th surface extending in the second direction along a second side among the second sides of the mask frame;
a (2-2)-th surface adjacent to a corner among the corners of the mask frame; and
a (2-3)-th surface extending in the first direction along a first side among the first sides of the mask frame.

6. The mask assembly of claim 5, wherein, in the plan view:
the (3-1)-th surface is disposed between the first surface and the (2-1)-th surface, and
the (3-2)-th surface is disposed between the first surface and the (2-3)-th surface.

7. The mask assembly of claim 4, wherein:
the first surface comprises:
a (1-1)-th surface adjacent to the frame opening;
a (1-2)-th surface extending in the second direction along a second side among the second sides of the mask frame; and
a (1-3)-th surface extending in the first direction along a first side among the first sides of the mask frame, and
in the plan view, the (3-1)-th surface is disposed between the (1-1)-th surface and the (1-2)-th surface, and
in the plan view, the (3-2)-th surface is disposed between the (1-1)-th surface and the (1-3)-th surface.

8. The mask assembly of claim 7, wherein:
the (3-1)-th surface extends in the second direction from a first side of the mask frame to another first side of the mask frame, the first side of the mask frame and the another first side of the mask frame opposing each other in the second direction, and
the (3-2)-th surface extends in the first direction from a second side of the mask frame to another second side of the mask frame, the second side of the mask frame and the another second side of the mask frame opposing each other in the first direction.

9. The mask assembly of claim 7, wherein:
the second surface is one of a plurality of second surfaces,
each of the plurality of second surfaces is disposed adjacent to a respective corner among the corners of the mask frame,
the (3-1)-th surface is disposed between second surfaces among the plurality of second surfaces adjacent to each other in the second direction, and
the (3-2)-th surface is disposed between second surfaces among the plurality of second surfaces adjacent to each other in the first direction.

10. The mask assembly of claim 1, wherein:
the mask frame comprises:
a first portion comprising the first surface and the second surface; and
a second portion extending from an upper surface of the first portion,
the second portion protrudes toward the frame opening further than the first portion, and
inner surfaces of the first portion and the second portion bounding respective portions of the frame opening are inclined from at least one of the first direction and the second direction.

11. The mask assembly of claim 10, wherein:
the frame opening comprises:
a first opening bounded by the inner surfaces of the first portion; and
a second opening bounded by the inner surfaces of the second portion, and
the first opening is fluidically connected with the second opening within the mask frame.

12. The mask assembly of claim 10, further comprising:
a first stick disposed between the mask frame and the mask in the third direction, the first stick extending in the first direction; and
a second stick disposed between the first stick and the mask in the third direction, the second stick extending in the second direction,
wherein each of the first stick and the second stick is disposed in a corresponding groove in an upper surface of the second portion.

13. A mask assembly comprising:
a stage;
a mask frame disposed on an upper surface of the stage, the mask frame comprising a frame opening; and
a mask disposed on an upper surface of the mask frame such that the upper surface of the mask frame faces the mask in a first direction and a lower surface of the mask frame faces the upper surface of the stage in a second direction opposite the first direction, wherein:
the lower surface of the mask frame comprises:
a first surface surrounding the frame opening in a plan view; and
a second surface adjacent to an edge of the mask frame in the plan view, and
a step connects the first surface with the second surface.

14. The mask assembly of claim 13, wherein a first distance between the second surface and the upper surface of the stage in the first direction is greater than a second distance between the first surface and the upper surface of the stage in the first direction.

15. The mask assembly of claim 14, wherein:
the lower surface of the mask frame further comprises a third surface surrounding the first surface in the plan view, and
a third distance between the third surface and the upper surface of the stage in the first direction is greater than the first distance.

16. The mask assembly of claim 15, wherein the second surface extends along at least one first side among first sides of the mask frame that extend in a third direction transverse to the first direction or at least one second side among second sides of the mask frame that extend in a fourth direction transverse to both the first direction and the third direction.

17. The mask assembly of claim 16, wherein the second surface is disposed further from the frame opening than the third surface.

18. The mask assembly of claim 13, wherein:
the second surface is one of a plurality of second surfaces, and
each of the plurality of second surfaces is disposed adjacent to a respective corner among corners of the mask frame.

19. The mask assembly of claim 18, wherein:
the lower surface of the mask frame further comprises a third surface extending in a third direction and a fourth direction in the plan view, both the third direction and the fourth direction being transverse to the first direction,
the third surface is disposed between second surfaces among the plurality of second surfaces that are adjacent to each other in the third direction and between second surfaces among the plurality of second surfaces that are adjacent to each other in the fourth direction, and
the third surface is disposed further from the frame opening than the first surface.

20. The mask assembly of claim 13, wherein the first surface directly contacts the upper surface of the stage.
